(19) United States
(12) Patent Application Publication
(10) Pub. No.: US 2022/0406564 A1
(43) Pub. Date: Dec. 22, 2022

(54) INDUCTIVELY COUPLED PLASMA GENERATING APPARATUS

(71) Applicant: FEMTO SCIENCE INC, Hwaseong-si (KR)

(72) Inventors: Moo Hwan KIM, Hwaseong-si (KR); Yeon Sook CHANG, Hwaseong-si (KR)

(73) Assignee: FEMTO SCIENCE INC, Hwaseong-si (KR)

(21) Appl. No.: 17/502,773

(22) Filed: Oct. 15, 2021

(30) Foreign Application Priority Data
Jun. 16, 2021 (KR) 10-2021-0078147

(51) Int. Cl. H01J 37/32

(52) U.S. Cl. CPC H01J 37/3211; H01J 37/32183; H01J 37/3244

(57) ABSTRACT

An inductively coupled plasma generating apparatus includes: a radio frequency (RF) generator; an impedance matcher connected to the RF generator; a gas supplier; and a first plasma head connected to the impedance matcher and the gas supplier to receive power and gas, that comprises a dielectric tube and a first antenna, wherein the first antenna is attached to the dielectric tube by being spirally wound along the length of the dielectric tube, and plasma is generated in the dielectric tube by a magnetic field created by the first antenna.

### CROSS REFERENCE TO RELATED APPLICATION

The present application claims priority to Korean Patent Application No. 10-2021-0078147, filed on Jun. 16, 2021, which is hereby incorporated by reference in its entirety.

### BACKGROUND

The present disclosure relates to an inductively coupled plasma generating apparatus that provides better portability by having an antenna coated or attached to a dielectric material.

Plasma is widely used in the manufacture of semiconductors, plasma display panels (PDP), liquid crystal displays (LCD), solar cells, etc. Some of the most common plasma processes include dry etching, plasma enhanced chemical vapor deposition (PECVD), sputtering, and ashing. Typically, plasmas such as capacitive coupled plasmas (CCP), inductively coupled plasmas (ICP), helicon plasmas, and microwave plasmas are used.

A plasma process is known to be directly linked to plasma parameters (electron density, electron temperature, ion flux, and ion energy). Notably, it was revealed that the electron density is closely related to throughput. This contributed to the active development of plasma sources with high electron density. Examples of such plasma source with high electron density include helicon plasmas, electron cyclotron resonance plasmas, and so forth. These plasma sources are known to produce high-density plasmas at low pressures. However, all of these plasma sources require the presence of a magnetic field, which could induce plasma instabilities and subsequently lead to a failure to control process reproducibility. Moreover, this makes the device expensive and bulky, and requires a magnetic field to be transferred to a substrate, thus giving an adverse effect on process uniformity. For this reason, these plasma sources have not found much use in industrial applications.

Meanwhile, ICP and CCP are commonly used in many applications. These two types of plasma sources are simple in structure and allows for linear control of processes. Also, they are less prone to plasma instabilities, which makes it relatively easy to ensure process reliability and allows them to find uses in various industrial fields.

### SUMMARY

Recently, various types of portable plasma equipment are being introduced in biological and medical fields, but they mostly use dielectric-barrier discharges or arc discharges and therefore their plasma density is low. Due to this, they have not shown remarkable treatment effects and the use of plasmas involves pain to the patient. In view of this, the present disclosure is directed to provide an inductively coupled plasma generating apparatus that generates high-density plasmas compared to dielectric barrier discharges because it generates plasmas by inductive coupling, and that therefore enhances the effects of plasma treatment and enables quick and easy use in industrial or medical situations because of its portability.

An exemplary embodiment of the present disclosure provides an inductively coupled plasma generating apparatus including: a radio frequency (RF) generator; an impedance matcher connected to the RF generator; a gas supplier; and a first plasma head connected to the impedance matcher and the gas supplier to receive power and gas, that comprises a dielectric tube and a first antenna, wherein the first antenna is attached to the dielectric tube by being spirally wound along the length of the dielectric tube, and plasma is generated in the dielectric tube by a magnetic field created by the first antenna.

Furthermore, the first antenna may be attached by printing to the dielectric tube in the form of a thin metal foil or in the form of a metal foil.

Furthermore, the first antenna may be attached in such a way that the number of turns per unit length of the dielectric tube is constant along the length of the dielectric tube.

Furthermore, the first antenna may be attached in such a way that the number of turns per unit length of the dielectric tube changes in a portion of the dielectric tube.

Furthermore, the first antenna may be attached in such a way that the number of turns per unit length of the dielectric tube increases.

Furthermore, a portion of the dielectric tube may be tapered along the length toward an outlet so that the cross-sectional area decreases gradually.

Another exemplary embodiment of the present disclosure provides an inductively coupled plasma generating apparatus including: a radio frequency (RF) generator; an impedance matcher connected to the RF generator; a gas supplier; and a plasma head connected to the impedance matcher and the gas supplier to receive power and gas, that comprises a head portion, a dielectric plate, and a second antenna, wherein the second antenna is attached by printing to the dielectric plate in the form of a thin metal film or in the form of a coil, and plasma is generated from gas supplied to the head portion by an electric field created by the second antenna.

Furthermore, the dielectric plate with the second antenna attached thereto may be sloped downward toward the center.

Furthermore, the second antenna may be spirally curved in such a way that the distance between neighboring loops changes as the curve gets farther away from the spiral center.

Furthermore, the second antenna may be formed in such a way that the distance between neighboring loops increases as the curve gets farther away from the spiral center.

Furthermore, the head portion may be detachable from the plasma head.

Furthermore, an inlet and an outlet may be formed on the head portion, the inlet and the outlet may be perpendicular to each other, and the outlet may have a plurality of jet holes.

Furthermore, the diameter of the plurality of jet holes in the head portion changes as the plurality of jet holes get farther away from the center of the head portion.

Furthermore, the diameter of the plurality of jet holes may decrease as the plurality of jet holes get farther away from the center of the head portion.

Furthermore, the diameter of the plurality of jet holes may increase as the plurality of jet holes get farther away from the center of the head portion.

Furthermore, the density of the plurality of jet holes may change as the plurality of jet holes get farther away from the center of the head portion.

Furthermore, the density of the plurality of jet holes may increase as the plurality of jet holes get farther away from the center of the head portion.

Furthermore, the density of the plurality of jet holes may decrease as the plurality of jet holes get farther away from the center of the head portion.

### BRIEF DESCRIPTION OF THE DRAWINGS

FIG. 1 schematically shows an inductively coupled plasma generating apparatus according to the present disclosure.

FIG. 2 schematically shows a configuration of an impedance matcher according to an embodiment.

FIG. 3 schematically depicts a first plasma head according to an embodiment.

FIG. 4 shows how the number of turns of an antenna per unit length of a dielectric tube of the first plasma head changes along the length of the dielectric tube.

FIG. 5 shows how the number of turns per unit length of the dielectric tube of the first plasma head changes along the length of the dielectric tube.

FIG. 6 shows an external profile of a second plasma head according to another embodiment.

FIG. 7 shows a second antenna of the second plasma head attached to a dielectric plate according to another embodiment.

FIG. 8 schematically depicts a cross-section of the second plasma head of FIG. 6 taken along the line A-A′ according to another embodiment.

FIG. 9 schematically depicts a cross-section of the second plasma head of FIG. 6 taken along the line A-A′ according to another embodiment.

FIG. 10 shows a head portion of the second plasma head according to another embodiment.

### DETAILED DESCRIPTION

As the disclosure allows for various changes and numerous embodiments, particular embodiments will be illustrated in the drawings and described in detail. However, it should be understood that the present disclosure is not limited to particular modes of practice, but encompasses all changes, equivalents, and substitutes included in the technical spirit and technical scope to be described below.

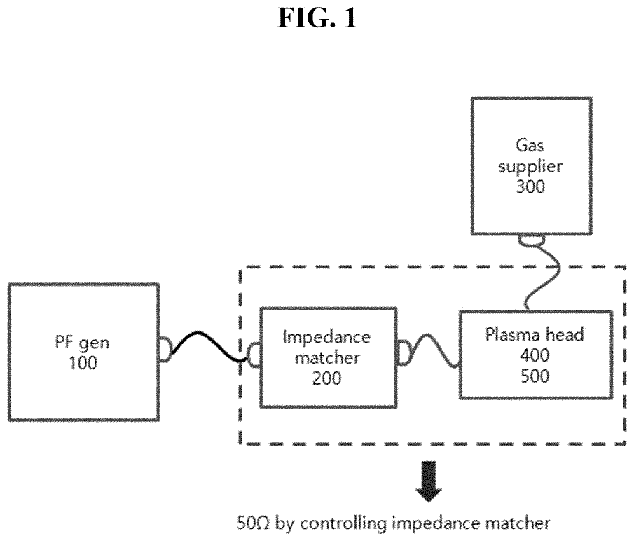

FIG. 1 schematically shows an inductively coupled plasma generating apparatus according to the present disclosure. Hereinafter, the present disclosure will be described in more detail with reference to the accompanying drawings to help understanding of the present disclosure. However, the following embodiment is provided only for ease of comprehension, and the subject matter of the present disclosure is not limited by the following embodiment.

FIG. 1 schematically shows an inductively coupled plasma generating apparatus 10 according to an embodiment of the present disclosure. Referring to FIG. 1, the inductively coupled plasma generating apparatus 10 may include a radio frequency (RF) generator 100, an impedance matcher 200, a gas supplier 300, and a plasma head 400 and 500.

The inductively coupled plasma generating apparatus 10 according to the present disclosure may be an apparatus for inducing an electric field by a magnetic field produced by an electric current and generating plasma by accelerating electrons by the induced electric field.

The RF generator 100 is a device for converting received alternating current power to a predetermined frequency and applying it to an antenna 420 and 520 of the plasma head 400 and 500, and may apply RF power to the plasma head 400 and 500 via the impedance matcher 200.

The RF generator 100 may have an operating frequency of several hundreds of kHz to several MHz, preferably, 13.56 MHz, 27.12 MHz, or 40. 68 MHz which are commonly-used frequencies. The RF generator 100 may show a first output and a second output that are opposite in phase.

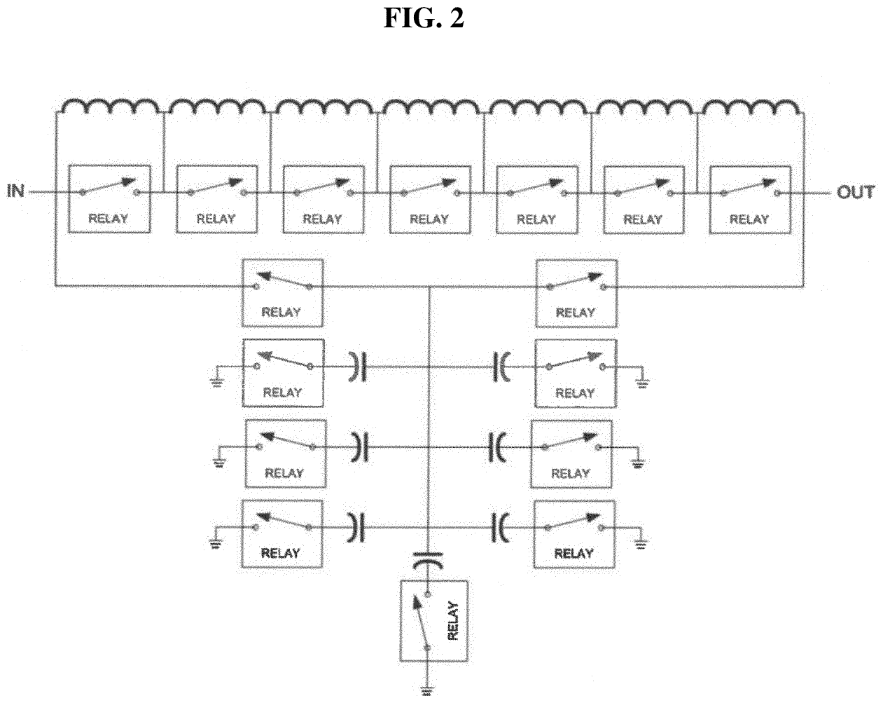

Referring to FIG. 2, the impedance matcher 200 may be a device that connects between the RF generator 100 and the plasma head 400 and 500 to reduce reflection loss caused by impedance mismatch between the RF generator 100 and the plasma head 400 and 500. The impedance matcher 200 of the present disclosure may include one or more of each of two types of devices selected from among simple passive components, such as inductors and capacitors, and relays. The impedance matcher 200 may be made small in size since a matching circuit is comprised of a minimum number of passive components and relays, by considering a matching condition for generating plasma in the plasma head 400 and 500.

The gas supplier 300 may be a device that is connected to the plasma head 400 and 500 to supply gas to the plasma head 400 and 500 to generate plasma. For example, the supplied gas may include, but not limited to, a mixture of one or more of the following: inert gases, such as argon (Ar), helium (He), and neon (Ne), oxygen (O₂), nitrogen (N₂), air, and carbon tetrafluoride (CF₄).

The RF generator 100 and the impedance matcher 200 may be disposed and connected together within a single main body, and the gas supplier 300 may be disposed within the main body or separately from the main body.

If the gas supplier 300 is disposed within the main body, the main body may include a valve (not shown) for regulating the amount of gas supply from the gas supplier 300 and a pressure gauge. The pressure gauge may be a device for displaying pressures at which gas is supplied.

The plasma head 400 and 500 is a component included in a handset, which is a small plasma instrument that is compact enough to grip in one hand, and may be a member that functions to generate plasma. The plasma head 400 and 500 may receive RF power generated by the RF generator from the impedance matcher 200 and generate plasma under atmospheric conditions. The plasma head 400 and 500 may include a first plasma head 400 and a second plasma head 500.

In one embodiment, referring to FIG. 3, the first plasma head 400 may include a dielectric tube 410 and a first antenna 420. The first plasma head 400 may receive gas for plasma generation from the gas supplier 300, and the supplied gas may be introduced into the dielectric tube 410.

The dielectric tube 410 may extend lengthwise, with an inlet formed on one end and an outlet formed on the other end. For example, the dielectric tube 410 may be made of, but not limited to, a material containing one or more of the following: glass, quartz, ceramic, alumina, sapphire, polyimide, polypropylene (PP), polytetrafluoroethylene, polyvinyl chloride (PVC), polyethylene, polystyrene, polyethylene terephthalate (PET), and polydimethylsiloxane (PDMS).

Referring to FIG. 4, a portion of the dielectric tube 410 may be tapered along the length toward the outlet so that the cross-sectional area decreases gradually. As the cross-sectional area becomes smaller, the density of generated plasma becomes higher and the range of plasma emission becomes narrower, which enables the user to do precision work using emitted plasma.

The first antenna 420 may be coated or attached to the dielectric tube 410 by being spirally wound lengthwise around the outer side of the dielectric tube 410. Since the first antenna 420 is coated or attached by printing in the form of a thin metal foil or in the form of a coil, the first antenna 420 and the dielectric tube 410 may be attached more firmly to each other without the need for any structure and provide better portability due to its small size.

The first antenna 420 may create a magnetic field in the dielectric tube 410 according to Ampere's right-hand rule when it receives RF power from the RF generator 100, and the magnetic field created in the dielectric tube 410 may induce a secondary current according to Maxwell's equations. An electric field created by the induced secondary current may convert a gas introduced into the first plasma head 400 into a plasma state.

Moreover, the secondary current and magnetic field created in the dielectric tube 410 may generate an electromagnetic force F that accelerates plasma in the direction of the outlet of the dielectric tube 410. Plasma is moved by a Coulomb force, and this Coulomb force acts in the direction of the outlet of the dielectric tube 410 to accelerate the plasma.

In one embodiment, the first antenna 420 may be coated or attached in such a way that the number of turns per unit length of the dielectric tube 410 is constant along the length of the dielectric tube 410.

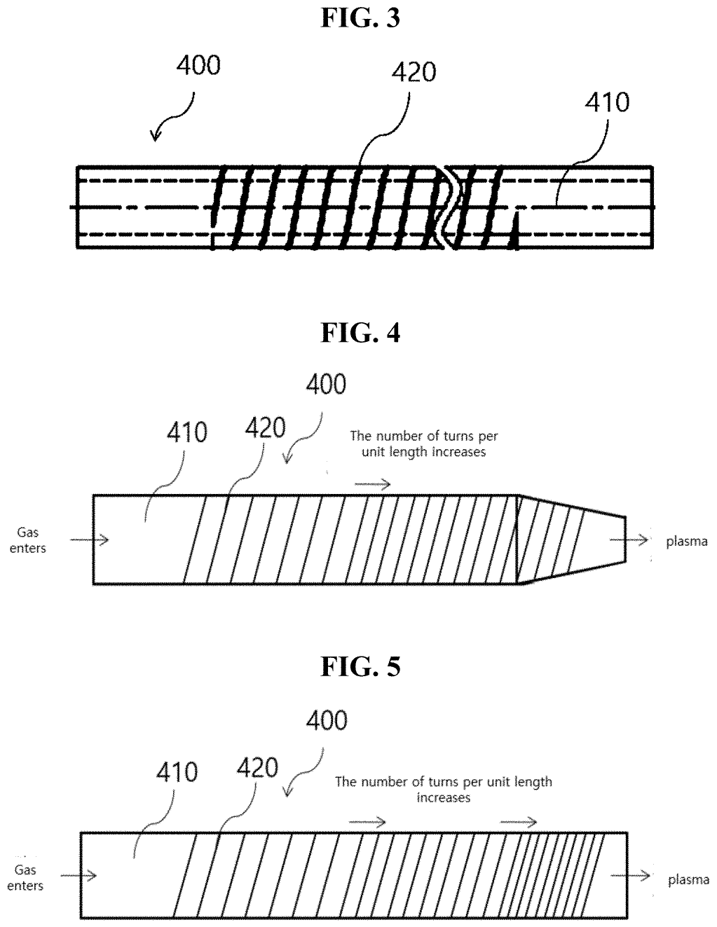

In another embodiment, referring to FIG. 5, the first antenna 420 may be coated or attached in such a way that the number of turns per unit length of the dielectric tube 410 changes along the length of the dielectric tube 410.

The first antenna 420 may be coated or attached in such a way that the number of turns per unit length of the dielectric tube 410 increases toward the outlet in a portion of the dielectric tube 410. If the first antenna 420 is coated or attached in such a way that the number of turns per unit length of the dielectric tube 410 increases toward the outlet, the intensity of a magnetic field created in the dielectric tube 410 increases toward the outlet of the dielectric tube 410. This may affect a generated plasma and accelerate it, thus further increasing the plasma density. Also, since the intensity of the magnetic field increases gradually, this may diminish the plasma's impact on the dielectric tube 410 where the plasma is generated, as compared to increasing the intensity of the magnetic field at a time, and therefore may minimize damage to the dielectric tube 410.

The first antenna 420 may be coated in such a way that the number of turns per unit length of the dielectric tube 410 decreases toward the outlet in a portion of the dielectric tube 410. If the number of turns per unit length of the dielectric tube 410 increases toward the outlet, the intensity of a created magnetic field decreases and therefore the generated plasma is decelerated, thereby reducing the plasma density.

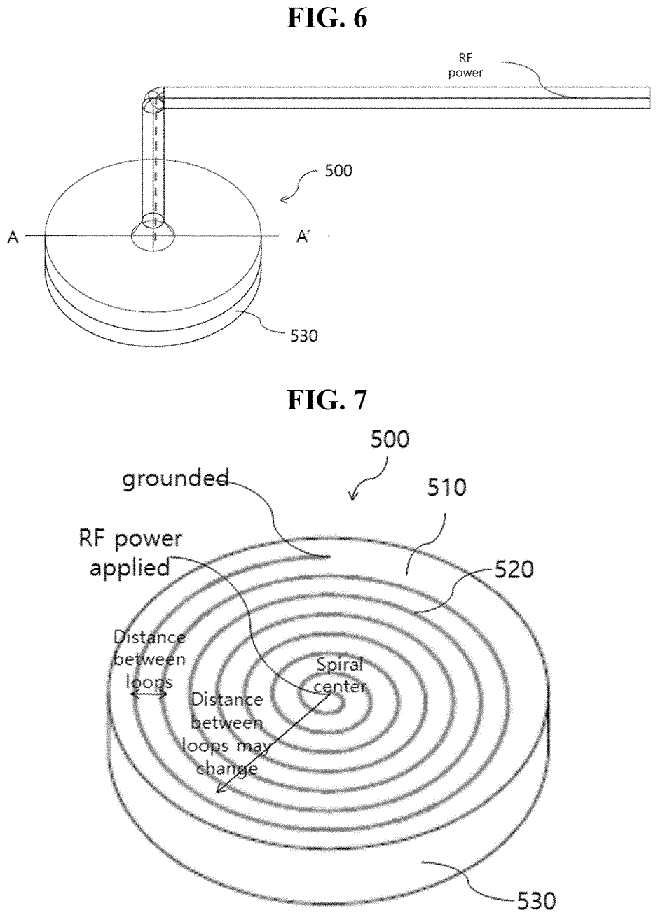

In another embodiment, referring to FIGS. 6 and 7, the second plasma head 500 may include a dielectric plate 510, a second antenna 520, and a head portion 530. The second plasma head 500 may receive gas for plasma generation from the gas supplier 300, and the supplied gas may be introduced into the head portion 530.

An inlet 531 may be formed on one side of the head portion 530, and an outlet 532 may be formed on one surface thereof. The inlet 531 may be an opening through which gas for plasma generation enters the head portion 530 from the gas supplier 300.

The outlet 532 may be formed one surface of the head portion 530, and the inlet 531 and the outlet 532 may be perpendicular to each other.

Gas introduced into the inlet 531 may form plasma in the head portion 530 by a magnetic field created by the second antenna 520 and exit through the outlet 532.

The outlet 532 may have a plurality of jet holes 532, like a shower head, on one surface of the head portion 530. Thus, when a generated plasma is accelerated with the magnetic field created by the second antenna 520, the plasma may be sprayed through the plurality of jet holes 532.

RF power may be applied to the second plasma head 500 from the RF generator 100 through the impedance matcher 200. Once RF power is applied, a vertical, time-varying electric field may be generated around the second antenna 520, and the time-varying electric field may induce a horizontal electric field in the head portion 530 through the dielectric plate 510. Plasma may be generated when electrons accelerated by the induced electric field collide with neutral gas.

The dielectric plate 510 may have a flat planar shape, and this shape may include, but not limited to, circular or polygonal such as rectangular or triangular.

For example, the dielectric tube 410 may be made of, but not limited to, a material containing one or more of the following: glass, quartz, ceramic, alumina, sapphire, polyimide, polypropylene (PP), polytetrafluoroethylene, polyvinyl chloride (PVC), polyethylene, polystyrene, polyethylene terephthalate (PET), and polydimethylsiloxane (PDMS).

The dielectric plate 510 may be placed inside the plasma head 500, a predetermined height apart from the plurality of jet holes 532, and may form an internal space inside the head portion 530 where plasma is generated and moves.

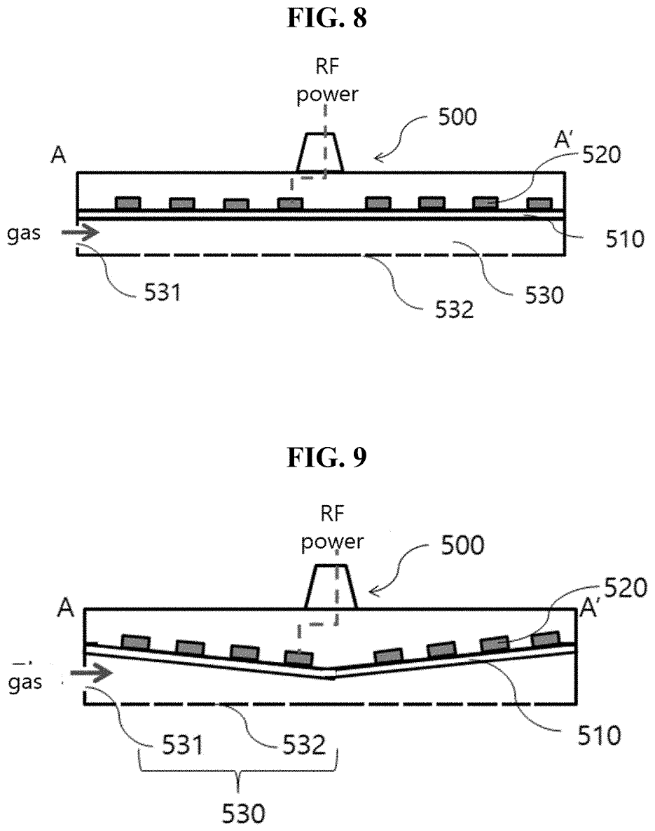

Referring to FIGS. 8 and 9, the dielectric plate 510 may be sloped downward toward the center, and a stronger electric field may be created at the center of the head portion 530 since the spiral center of the second antenna 520 is closer to the center of the head portion 530. Accordingly, the density of plasma generated in the internal space of the head portion 530 becomes higher toward the center.

The second antenna 520 may be attached to an upper side of the dielectric plate 510. The second antenna 520 may be printed on the upper side of the dielectric plate 510 in the form of a thin metal foil or attached to it by printing in the form of a coil, thereby improving the attachment and making the plasma head 500 smaller in size.

Referring to FIG. 7, the second antenna 520 may be coated or attached to the dielectric plate 510 by printing. The second antenna 520 may be spirally curved, and the second antenna 520 may be formed in such a way that its curvature decreases gradually the farther away from the spiral center.

In one embodiment, the second antenna 520 may be spirally curved in such a way that neighboring loops are spaced evenly at preset intervals.

In another embodiment, the second antenna 520 may be attached or coated by printing in such a way that the distance between neighboring loops changes as the curve gets farther away from the spiral center—that is, the distance between loops increases or decreases as the curve gets farther away from the spiral center. If the distance between loops increases as the curve gets farther away from the spiral center, the electric field is more concentrated near the spiral center and therefore plasma with higher density may be generated near the center of the head portion 530. If the distance between loops decreases as the curve gets farther away from the spiral center, the electric field is stronger the farther away from the spiral center and therefore plasma with higher density may be generated the farther away from the center of the head portion 530.

The second antenna 520 may be connected to the RF generator 100 through the impedance matcher 200. RF power may be applied to the spiral center of the second antenna 520, and a longitudinal end of the second antenna 520 may be grounded.

The second antenna 520 may be coated or attached in the form of a thin metal foil or in the form of a metal coil. If the second antenna 520 is in the form of a metal coil, its cross-section may be circular or rectangular. Since the second antenna 520 is attached or coated firmly to an inner surface of the dielectric plate 510, the second antenna 520 and the dielectric plate 510 may be attached more firmly to each other. Also, the second plasma head 500 may be reduced in height and therefore the second plasma head 500 may be made smaller in size, thereby providing better portability.

The head portion 530 may be detachably coupled to the plasma head 500. The plurality of jet holes 532 in the head portion 530 may be formed in various patterns, and the head portion 530 may be replaced depending on what purpose the inductively coupled plasma generating apparatus according to the present disclosure serves.

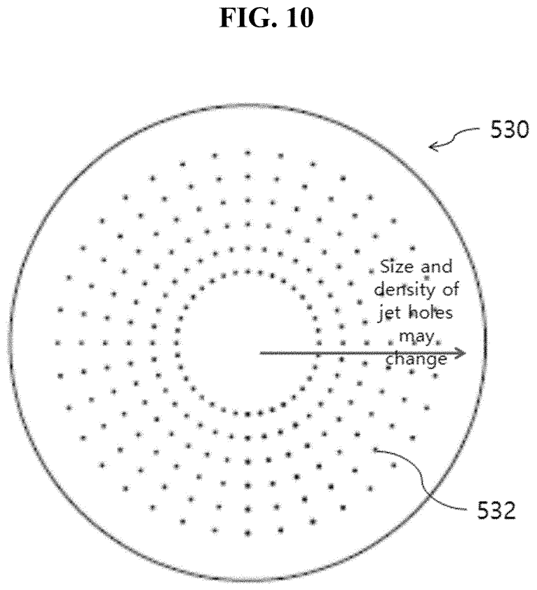

Referring to FIG. 10, the diameter of the plurality of jet holes 532 in the head portion 530 may change as they get farther away from the center of the head portion 530. The plurality of jet holes 532 may become larger or smaller in size as they get farther away from the center of the head portion 530.

The diameter of the jet holes 532 in the head portion 530 may change with the distance between neighboring loops of the second antenna 520. If the distance between neighboring loops of the second antenna 520 increases as the curve gets farther away from the spiral center, the plasma density is higher at the center of the head portion 530 and therefore the diameter of the jet holes 532 in the head portion 530 may become larger toward the center. If the distance between neighboring loops of the second antenna 520 decreases as the curve gets farther away from the spiral center, the plasma density is lower at the center of the head portion 530 and therefore the diameter of the jet holes 532 in the head portion 530 may become smaller toward the center.

The density of the jet holes 532 in the head portion 530 may change as they get farther away from the center of the head portion 530. The density of the jet holes 532 in the head portion 530 may increase or decrease as they get farther away from the center of the head portion 530.

The density of the jet holes 532 in the head portion 530 may change with the distance between neighboring loops of the second antenna 520. If the distance between neighboring loops of the second antenna 520 increases as the curve gets farther away from the spiral center, the plasma density is higher at the center of the head portion 530 and therefore the density of the jet holes 532 in the head portion 530 may become higher toward the center. If the distance between neighboring loops of the second antenna 520 decreases as the curve gets farther away from the spiral center, the plasma density is lower at the center of the head portion 530 and therefore the density of the jet holes 532 in the head portion 530 may become lower toward the center.

While the present technology has been described in the foregoing with reference to an embodiment, the technology is by no means limited to the embodiment. The embodiment may be modified and altered without departing from the gist and scope of the technology, and those skilled in the art will appreciate that such modifications and alterations fall within the scope of the present technology.

The inductively coupled plasma generating apparatus according to the present disclosure may improve provide better portability by making the plasma head smaller in size, since an antenna is attached to a dielectric material. Also, the inductively coupled plasma generating apparatus allows for high-density plasma generation, which may enhance plasma treatment efficiency and enable quick and easy use in industrial or medical situations.

Moreover, the antenna is disposed in such a way that the number of turns per unit length of the dielectric tube changes, thereby diminishing sudden impacts the dielectric material may receive due to high-density plasma generation.

1. An inductively coupled plasma generating apparatus comprising:
a radio frequency (RF) generator;
an impedance matcher connected to the RF generator;
a gas supplier; and
a first plasma head connected to the impedance matcher and the gas supplier to receive power and gas, that comprises a dielectric tube and a first antenna,
wherein the first antenna is attached to the dielectric tube by being spirally wound along the length of the dielectric tube, and plasma is generated in the dielectric tube by a magnetic field created by the first antenna.

2. The inductively coupled plasma generating apparatus of claim 1, wherein the first antenna is attached by printing to the dielectric tube in the form of a thin metal foil or in the form of a metal foil.

3. The inductively coupled plasma generating apparatus of claim 1, wherein the first antenna is attached in such a way that the number of turns per unit length of the dielectric tube is constant along the length of the dielectric tube.

4. The inductively coupled plasma generating apparatus of claim 1, wherein the first antenna is attached in such a way that the number of turns per unit length of the dielectric tube changes in a portion of the dielectric tube.

5. The inductively coupled plasma generating apparatus of claim 4, wherein the first antenna is attached in such a way that the number of turns per unit length of the dielectric tube increases.

6. The inductively coupled plasma generating apparatus of claim 3, wherein a portion of the dielectric tube is tapered along the length toward an outlet so that the cross-sectional area decreases gradually.

7. An inductively coupled plasma generating apparatus comprising:
a radio frequency (RF) generator;
an impedance matcher connected to the RF generator;
a gas supplier; and
a plasma head connected to the impedance matcher and the gas supplier to receive power and gas, that comprises a head portion, a dielectric plate, and a second antenna,
wherein the second antenna is attached by printing to the dielectric plate in the form of a thin metal film or in the form of a coil, and plasma is generated from gas supplied to the head portion by an electric field created by the second antenna.

8. The inductively coupled plasma generating apparatus of claim 7, wherein the dielectric plate with the second antenna attached thereto is sloped downward toward the center.

9. The inductively coupled plasma generating apparatus of claim 7, wherein the second antenna is spirally curved in such a way that the distance between neighboring loops changes as the curve gets farther away from the spiral center.

10. The inductively coupled plasma generating apparatus of claim 9, wherein the second antenna is formed in such a way that the distance between neighboring loops increases as the curve gets farther away from the spiral center.

11. The inductively coupled plasma generating apparatus of claim 7, wherein the head portion is detachable from the plasma head.

12. The inductively coupled plasma generating apparatus of claim 7, wherein an inlet and an outlet are formed on the head portion, the inlet and the outlet are perpendicular to each other, and the outlet has a plurality of jet holes.

13. The inductively coupled plasma generating apparatus of claim 12, wherein the diameter of the plurality of jet holes in the head portion changes as the plurality of jet holes get farther away from the center of the head portion.

14. The inductively coupled plasma generating apparatus of claim 13, wherein the diameter of the plurality of jet holes decreases as the plurality of jet holes get farther away from the center of the head portion.

15. The inductively coupled plasma generating apparatus of claim 13, wherein the diameter of the plurality of jet holes increases as the plurality of jet holes get farther away from the center of the head portion.

16. The inductively coupled plasma generating apparatus of claim 12, wherein the density of the plurality of jet holes changes as the plurality of jet holes get farther away from the center of the head portion.

17. The inductively coupled plasma generating apparatus of claim 16, wherein the density of the plurality of jet holes increases as the plurality of jet holes get farther away from the center of the head portion.

18. The inductively coupled plasma generating apparatus of claim 16, wherein the density of the plurality of jet holes decreases as the plurality of jet holes get farther away from the center of the head portion.

19. The inductively coupled plasma generating apparatus of claim 4, wherein a portion of the dielectric tube is tapered along the length toward an outlet so that the cross-sectional area decreases gradually.
